(19) United States
(12) Patent Application Publication
(10) Pub. No.: US 2022/0164507 A1
(43) Pub. Date: May 26, 2022

(54) ELECTRONIC SYSTEM-LEVEL REPRODUCIBLE PARALLEL SIMULATION METHOD IMPLEMENTED BY WAY OF A DISCRETE EVENT SIMULATION MULTICORE COMPUTING SYSTEM

(71) Applicants: COMMISSARIAT A L'ENERGIE ATOMIQUE ET AUX ENERGIES ALTERNATIVES, PARIS (FR); Centre national de la recherche scientifique, Paris (FR); UNIVERSITE CLAUDE BERNARD LYON 1 (UCBL), VILLEURBANNE CEDEX (FR); ECOLE NORMALE SUPERIEURE DE LYON (ENS), LYON (FR)

(72) Inventors: Gabriel Busnot, Bagneux (FR); Matthieu Moy, Lyon (FR); Tanguy Sassolas, Gif-Sur-Yvette (FR)

(21) Appl. No.: 17/528,110

(22) Filed: Nov. 16, 2021

(30) Foreign Application Priority Data
Nov. 25, 2020 (FR) 2012150

(51) Int. Cl. G06F 30/3308

(52) U.S. Cl. CPC G06F 30/3308

(57) ABSTRACT

An electronic system-level reproducible parallel discrete event simulation method implemented by way of a multicore computing system, the simulation method includes a succession of evaluation phases, implemented by a simulation kernel executed by the computing system, comprising the following steps: parallel scheduling of processes; dynamically detecting shared addresses; avoiding access conflicts to addresses of the shared memory; verifying access conflicts to shared memory addresses; rolling back, upon detecting at least one conflict; and generating an execution trace for the subsequent identical reproduction of the simulation.

### CROSS-REFERENCE TO RELATED APPLICATIONS

This application claims priority to foreign French patent application No. FR 2012150, filed on Nov. 25, 2020, the disclosure of which is incorporated by reference in its entirety.

### FIELD OF THE INVENTION

The invention relates to an electronic system-level reproducible parallel simulation method implemented by way of a discrete event simulation multicore computing system.

The invention relates to the field of system-on-chip design tools and methodologies, and aims to increase the execution speed of virtual prototyping tools in order to speed up the initial design phases of systems-on-chips.

### BACKGROUND

A system-on-chip may be broken down into two components: hardware and software. The software, which represents an increasing share of the development outlay for systems-on-chips, has to be validated as early as possible. In particular, it is not possible to wait for the manufacture of the first hardware prototype due to cost and launch delays. To address this need, some high-level modelling tools have been developed. These tools make it possible to describe a high-level virtual prototype of the hardware platform. The software intended for the system undergoing design may then be executed and validated on this virtual prototype.

The complexity of modern systems-on-chips also makes them complex to optimize. The most suitable architectural choices for the function of the system and for the associated software involve multiple criteria and are difficult to optimize beyond a certain point. Using virtual prototypes then makes it possible to perform fast architectural exploration. This consists in measuring the performance (for example speed, power consumption, temperature) of a variety of different configurations (for example memory size, cache configuration, number of cores) in order to choose the one exhibiting the best compromise. The quality of the results provided by the initial exploration phase will have a large impact on the quality and the competitiveness of the final product. The speed and the reliability of the simulation tools is therefore a crucial challenge.

The majority of these tools are based on the SystemC/TLM2.0 [SYSC, TLM] C++ hardware description library described in the IEEE 1666™-2011 standard.

SystemC is a hardware description language for creating virtual prototypes of digital systems. These virtual prototypes may then be simulated using a discrete event simulator. The SystemC standard indicates that this simulator should comply with coroutine semantics, i.e. that simulated concurrent processes of a model are executed sequentially. This limits the use of the computing resources available on a machine to a single core at a time.

The invention proposes a parallel SystemC simulation kernel that supports all types of model (such as RTL, the acronym for “Register Transfer Level” and TLM, the acronym for “Transactional Level Modelling”).

SystemC is used as an explanatory support for the present description since it is advantageously applicable to virtual prototyping, but any discrete event simulation system applied to electronic systems is able to benefit from the described invention, such as Verilog or VHDL.

Multiple approaches applicable to various families of models have been taken for parallelizing SystemC, as follows:

A first technique aims to prevent errors linked to parallelization using static code analysis as in [SCHM18]. A compiler specializing in SystemC programs makes it possible to analyse the source code of a model. It focuses on the transitions, that is to say the code portions executed between two calls to the synchronization primitive “wait( )”. Since these portions have to be evaluated atomically, the compiler looks for any dependencies between these transitions in order to determine whether they are able to be evaluated in parallel. This technique fine-tunes the analysis by distinguishing between the modules and the ports in order to limit detections of false positives. A static schedule of the processes may then be computed. However, in the context of a TLM model, all processes accessing for example one and the same memory will be scheduled sequentially, making this approach ineffective.

Another approach encountered in [SCHU10] consists in executing all of the processes of one and the same delta cycle in parallel. This family of techniques generally aims to model on the RTL level. In order to remain compliant with the SystemC standard and to avoid simulation errors caused by shared resources, it is up to the developer of the model to protect them. Moreover, in the event of multiple access operations to a shared resource from a plurality of processes, the order of the access operations is not monitored, thereby compromising the reproducibility of the simulation.

In order to better support the simulation of TLM models, [MELL10, WEIN16] use temporal decoupling. This consists in dividing the model into a set of groups of temporally independent processes. These techniques apply the principles of the parallel simulation to discrete events. They consist in authorizing various processes to take place at different dates while at the same time guaranteeing that these never receive events triggered at past dates. [MELL10] uses the sending of dated messages to synchronize the processes and [WEIN16] introduces communication delays between two groups of processes, thus allowing one of them to adopt a lead at most equal to the delay of the communication channel without the risk of missing a message. However, these approaches are restricted to the use of specific communication channels between two groups of processes and are better suited to what are known as approximately timed low-level TLM models. What are known as loosely timed models, using high-level simulation techniques such as direct memory access (DMI, the acronym for “Direct Memory Interface”), are often incompatible with these methods.

Some process areas are also used in [SCHU13]. A process area is the name given to all of the processes and associated resources able to be accessed by these processes. The processes in one and the same area are executed sequentially, guaranteeing their atomicity. The processes in the various areas are in turn executed in parallel. To preserve atomicity, when a process in one area attempts to access resources belonging to another area (variables or functions belonging to a module located in another area), it is interrupted, its context is migrated to the targeted area and then it is relaunched sequentially with respect to the other processes in its new area. However, this technique does not guarantee the atomicity of processes in all cases. If, for example, a process Pₐ, modifies a state Sₐ, in the same area before changing area to modify a state S_{b}. During this time, a process P_{b} modified S_{b} before changing area to modify Sₐ. At this stage, each process will see the modifications made by the other process during the current evaluation phase, violating the evaluation atomicity of the processes. In addition, in the presence of a shared global memory, all of the processes would be sequentialized upon the access operation to this memory, thus exhibiting performance close to a fully sequential simulation.

In [MOY13], it is possible to specify the duration of a task and to execute it asynchronously in a dedicated system thread. Two tasks that overlap in time may thus run simultaneously. This approach works best for lengthy and independent processes. However, the atomicity of the processes is no longer guaranteed if they interact with one another during their execution, such as for example by accessing one and the same shared memory.

In the solution proposed in [VENT16], all of the processes of one and the same delta cycle are executed in parallel. To preserve the evaluation atomicity of the processes, [VENT16] relies on the instrumentation of the memory access operations. Each memory access operation thus has to be accompanied by a call to an instrumentation function, which will verify whether the access operation concerns a previously declared address shared by the user. In this case, only the first process to access one of the shared addresses is authorized to continue in the parallel evaluation of the processes. The others have to continue their execution in a sequential phase. Dependency graphs between memory access operations are also constructed during the instrumentation of the memory access operations. At the end of each evaluation phase, these graphs are analysed in order to verify that all of the processes have actually been evaluated atomically. If they have not, the user has forgotten to declare certain shared addresses.

One approach targeting a similar problem is proposed in [LE14]. The objective therein is to verify the validity of a model by demonstrating that, for a given input, all of the possible process schedules give the same output. To verify this, it is formally verified that all of the possible schedules give the same output. A static C model is generated from the C++ model for this purpose. This approach however understands determinism in the sense that the processes are independent at scheduling. This assumption turns out to be incorrect for higher-level models such as TLM models in which interactions take place during the evaluation phase and not during the update phase. Such formal verification would be completely impossible for a complex system and is applicable only to low-dimension IPs.

Finally, [JUNG19] proposes performing speculative temporal decoupling using the “fork(2)” Linux system call. The fork(2) function makes it possible to duplicate a process. Temporal decoupling refers here to a technique used in TLM modelling called “loosely timed”, which consists in authorizing a process to take the lead over the global time of the simulation and to synchronize only at time intervals of a constant duration, called a quantum. This greatly accelerates the simulation speed, but introduces temporal errors. For example, a process may, at the local date t₀, receive an event sent by another process the local date of which was t₁, with t₁ <tₒ, violating the causality principle. To improve the accuracy of these models using temporal decoupling, [JUNG19] implements a fork(2)-based rollback technique. To save the state of the simulation, said simulation is duplicated using a call to fork(2). One of the two versions of the simulation will then run with a delay quantum over the other. In the event of a timing error during a quantum, the delayed version may then force the synchronizations when it reaches this quantum and thus avoid the error.

[JUNG19] uses the rollback on the process level to correct simulation timing errors. However, the simulation speed is still limited by the single-core performance of the host machine. In the context of a parallel simulation, fork(2) no longer makes it possible to save the state of the simulation since the threads are not duplicated by fork(2), making this approach inapplicable in the case of the invention. In addition, correcting the timing errors of a model using the quantums constitutes, in the strict sense, an atomicity violation of the processes, these being interrupted by the simulation kernel without a call to the primitive wait( ). This functionality may be desirable for some, but is incompatible with the desire to comply with the SystemC standard.

[VENT16] uses a method in which concurrent processes of a SystemC simulation are executed in parallel execution queues each associated with a specific logic core of the host machine. A method for analysing dependencies between the processes is implemented in order to guarantee their atomicity. [VENT16] relies on the manual declaration of shared memory areas in order to guarantee a valid simulation. However, it is often impossible to ascertain these areas a priori in the event of dynamic allocation of memory or virtualized memory, as is often the case under an operating system. [VENT16] uses a parallel phase and an optional sequential phase in the event of processes that are pre-empted for prohibited access to a shared memory during the parallel phase. Any parallelism is prevented during this sequential phase and leads to significant slowing.

[VENT16] establishes dependencies through multiple graphs that are constructed during the evaluation phase. This requires burdensome synchronization mechanisms that greatly slow down the simulation in order to guarantee the integrity of the graphs. [VENT16] additionally requires the global dependency graph to be completed and analysed at the end of each parallel phase, slowing the simulation down even more. [VENT16] manipulates the execution queues monolithically, that is to say that, if one process of the simulation is sequentialized, all of the processes in the same execution queue will also be sequentialized.

[VENT16] proposes to reproduce a simulation based on a linearization of the dependency graph of each evaluation phase stored in a trace. This means having to sequentially evaluate processes that may prove to be independent, such as for the graph (1→2, 1→3), which would be linearized to give (1, 2, 3), whereas 2 and 3, which are not dependent on one another, may be executed in parallel.

### SUMMARY OF THE INVENTION

One aim of the invention is to overcome the problems cited above, and notably to speed up the simulation while at the same time keeping it reproducible while at the same time improving performance in contexts with very strong interactions.

What is proposed, according to one aspect of the invention, is an electronic system-level reproducible parallel discrete event simulation method implemented by way of a multicore computing system, said simulation method comprising a succession of evaluation phases, implemented by a simulation kernel executed by said computing system, comprising the following steps:
parallel scheduling of processes;
dynamically detecting shared addresses of at least one shared memory of a simulated electronic system by concurrent processes, at addresses of the shared memory, using a state machine, respectively associated with each address of the shared memory;
avoiding access conflicts to addresses of the shared memory by concurrent processes, by pre-empting a process by way of the kernel when said process introduces a “read after write” or “write after read or write” interprocess dependency or when the process simulates a processor whose privilege level changes from the lower level to a higher level;
verifying access conflicts to shared memory addresses by analysing the interprocess dependencies using a trace of the access operations to the shared memory addresses of each evaluation phase and searching for cycles in an interprocess dependency graph;
rolling back, upon detecting at least one conflict, in order to re-establish a past state of the simulation after determining a conflict-free execution order of the processes of the conflicting evaluation phase during which the conflict is detected, in a new simulation that is identical up to the excluded conflicting evaluation phase; and
generating an execution trace for the subsequent identical reproduction of the simulation.

Such a method allows parallel simulation of SystemC models in compliance with the standard. In particular, this method allows the identical reproduction of a simulation, which facilitates debugging. It supports loosely timed TLM simulation models using temporal decoupling by using a simulation quantum and direct memory access (DMI) operations, which are highly useful for achieving high simulation speeds. Lastly, it makes it possible to autonomously and dynamically detect shared addresses, and therefore supports the use of virtual memories, which is essential to the execution of operating systems.

According to one mode of implementation, the parallel scheduling of processes uses queues of at least one process, the processes in one and the same queue being executed sequentially by a system thread associated with a logic core.

Processes placed in different queues are thus executed in parallel. Since the process queues are able to be populated manually or automatically, it is possible for example to combine processes that risk having dependencies or to rebalance the load of each core by migrating processes from one queue to another.

In one embodiment, the execution of a queue of at least one process, the execution of which was suspended following the pre-empting of one of its processes by the kernel, is resumed in a subsequent parallel sub-phase if the pre-empting is due to said process introducing a “read after write” or “write after read or write” interprocess dependency, or is resumed in a subsequent sequential sub-phase if the pre-empting is due to the logic core executing the process changing from a lower privilege level to a higher privilege level.

It is thus ensured that no “read after write” or “write after read or write” dependency is able to be introduced between memory access operations performed after a change in privilege level of the logic cores performing these access operations from a lower level to a higher level.

In one mode of implementation, the rollback uses backups of states of the simulation during the simulation that are performed by the simulation kernel.

It is thus possible to re-establish the simulation in each of the saved states and to resume it at this point. Performed at regular intervals, these backups make it possible to penalize the execution to a sparing extent upon a rollback.

According to one mode of implementation, the state machine of an address of the shared memory comprises the following four states:

“no access” (No_access), when the state machine has been reset, without a queue of at least one process defined as owner of the address;
“owned” (Owned) when the address has been accessed by a single queue of at least one process including once in write mode, said queue then being defined as owner of the address;
“in read exclusive mode” (Read_exclusive) when the address has been accessed exclusively in read mode by a single queue of at least one process, said queue then being defined as owner of the address; and
“in read shared mode” (Read_shared) when the address has been accessed exclusively in read mode by at least two queues of at least one process, without a queue defined as owner of the address.

It is thus possible to simply classify the addresses according to the access operations that have been performed there. The state of an address will then determine the access operations authorized there, and do so via a minimum memory footprint.

In one mode of implementation, the pre-empting of a process by the kernel is determined when:

write access is requested to an address of the shared memory by a queue of at least one process that is not the owner in the state machine of the address, and the current state is other than “no access”; or
read access is requested to an address of the shared memory, the state machine of which is in the “owned” or “read exclusive” state, by a queue of at least one process other than the queue owning the address in the state machine of the address.

No dependency between queues of at least one process is thus able to be introduced during an evaluation sub-phase.

According to one mode of implementation, all of the state machines of the addresses of the shared memory are regularly reset to the “no access” state.

It is thus preferable to maximize parallelism by freeing up the states of the addresses observed in previous quantums. Specifically, the advantage of using quantums is that of not having to consider the history of access operations to the memory since the start of the execution of the simulation. In addition, between various quantums, an address may be used differently, and the state best corresponding thereto may change.

In one mode of implementation, all of the state machines of the addresses of the shared memory are reset to the “no access” state during the evaluation phase following the pre-empting of a process.

The pre-empting of a process may thus prove to be characteristic of a change in use of an address in the simulated program, and it is preferable to maximize parallelism by freeing up the states of the addresses observed in previous quantums.

According to one mode of implementation, access conflicts to shared memory addresses during each evaluation phase are verified asynchronously, during the execution of subsequent evaluation phases.

The access conflict verification thus does not block the progress of the simulation. This method advantageously contributes to reducing simulation time.

In one mode of implementation, the execution trace for the subsequent identical reproduction of the simulation comprises a list of numbers representative of evaluation phases associated with a partial evaluation order of the processes defined by the interprocess dependency relationships of each evaluation phase.

It is thus possible to execute the simulation identically again, which facilitates debugging of the application and of the simulated platform.

According to one mode of implementation, a rollback, upon detection of at least one conflict, re-establishes a past state of the simulation, and then reproduces the simulation identically up to the evaluation phase that produced the conflict and then executes its processes sequentially.

It is thus ensured that the conflict that required a rollback will not occur again. The simulation may then continue its progress.

In one mode of implementation, a rollback, upon detection of at least one conflict, re-establishes a past state of the simulation, and then reproduces the simulation identically up to the evaluation phase that produced the conflict and then executes its processes in a partial order deduced from the dependency graph of the evaluation phase that produced the conflict after having removed one arc per cycle therefrom.

It is thus ensured that the conflict that required a rollback will not occur again. In addition, the partially parallel execution of the conflicting evaluation phase exhibits an acceleration in comparison with a sequential execution of this same phase. The simulation may then continue its progress.

According to one mode of implementation, a state of the simulation is saved at regular intervals of evaluation phases.

It is thus possible to re-establish the simulation in a relatively close previous state in the event of a conflict. This is a compromise. The smaller the intervals, the more this will have an impact on the overall performance during backups, but the excess cost of a rollback will be lower. By contrast, the larger the intervals, the less this will have an impact on the simulation times, but a rollback will be more costly.

In one mode of implementation, a state of the simulation is saved at intervals of evaluation phases that increase in the absence of detection of a conflict and decrease following detection of a conflict.

It is thus possible to limit the number of backups during phases of the simulation that do not exhibit conflicts, thereby increasing the simulation performance.

What is also proposed, according to another aspect of the invention, is a computer program product comprising computer code able to be executed by a computer, stored on a computer-readable medium and designed to implement a method as described above.

### BRIEF DESCRIPTION OF THE DRAWINGS

The invention will be better understood from studying a few embodiments described by way of completely non-limiting examples and illustrated by the appended drawings, in which:

FIG. 1 schematically illustrates the phases of a SystemC simulation according to the prior art;

FIG. 2 schematically illustrates one mode of implementation of the electronic system-level reproducible parallel simulation method implemented by way of a discrete event simulation multicore computing system, according to one aspect of the invention;

FIG. 3 schematically illustrates parallel scheduling of processes, according to one aspect of the invention;

FIG. 4 schematically illustrates a state machine associated with a shared memory address, according to one aspect of the invention;

FIG. 5 schematically illustrates a data structure for recording a trace of the memory access operations performed by each of the execution queues of the simulation, according to one aspect of the invention;

FIG. 6 schematically illustrates an algorithm for extracting a partial process execution order according to an interprocess dependency graph, according to one aspect of the invention;

FIG. 7 schematically illustrates the rollback procedure in the event of detection of an error during the simulation, according to one aspect of the invention;

FIG. 8 schematically illustrates a trace for identically reproducing a simulation, according to one aspect of the invention;

FIG. 9 schematically illustrates a process dependency table, according to one aspect of the invention, and

FIG. 10 schematically illustrates a case solved by the invention but not solved by the prior art.

### DETAILED DESCRIPTION

Throughout the figures, elements having identical references are similar. The invention is based on monitoring memory access operations in association with a method for detecting shared addresses, and with a system for re-establishing a previous state of the simulation and with a simulation reproduction system.

To address the need to speed up virtual prototyping tools, modelling techniques are based on increasingly high-level abstractions. This has made it possible to benefit from the compromise between speed and accuracy. Specifically, a less detailed model requires less computing in order to simulate a given action, increasing the number of actions able to be simulated within a given time. However, it becomes increasingly difficult to increase the abstraction level of models without compromising the validity of the simulation results. Since excessively inaccurate simulation results fatally lead to design errors that are costly later on, it is important to keep a sufficient accuracy level.

Faced with the difficulty of further increasing the abstraction level of virtual prototypes, the present invention proposes to resort to parallelism in order to speed up the simulation of systems-on-chips. In particular, use is made of a technique for the parallel simulation of SystemC models.

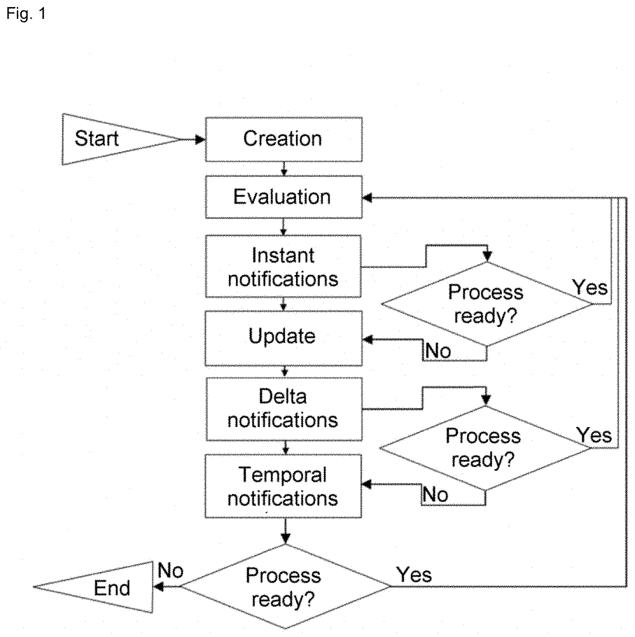

A SystemC simulation may be broken down into three phases, as illustrated in FIG. 1: creation, during which the various modules of the model are initialized; evaluation, during which the new state of the model is computed according to its current state by executing the various processes of the model; and update, during which the results of the evaluation phase are propagated into the model for the next evaluation phase.

Following the creation performed at the start of simulation, the evaluation and update phases alternate until the end of the simulation, in accordance with the execution diagram of FIG. 1. The evaluation phase is triggered by three types of notification: instant, delta and temporal. An instant notification has the effect of programming the execution of additional processes directly during the current evaluation phase. A delta notification programs the execution of a process in a new evaluation phase that takes place at the same date (time of the simulation). A temporal notification, lastly, programs the execution of a process at a later date. It is this type of notification that causes the simulated time to move forward. The evaluation phase requires significantly more computing time than the other two. It is therefore speeding up this phase that affords the greatest gain and that forms the subject of the invention.

In order to facilitate analysis and debugging of the simulated model and the simulated software, the SystemC standard stipulates that a simulation is reproducible, that is to say that it always produces the same result from one execution to the next when the same inputs are present. To this end, it is imposed that the various processes programmed to run during a given evaluation phase are executed while complying with the coroutine semantics, and therefore atomically. This makes it possible to obtain an identical simulation result between two executions with the same input conditions. Atomicity is a property used in concurrent programming to denote an operation or a set of operations of a program that run entirely without being able to be interrupted before they finish running, and without an intermediate state of the atomic operation being able to be observed.

This rule imposes, a priori, the use of a single core on the machine hosting the simulation, thereby greatly limiting the performance able to be achieved on modern computing machines having multiple cores. However, it is actually only essential to comply with the coroutine semantics: the processes have to be executed in a manner equivalent to a sequential execution, that is to say atomically, but not necessarily sequentially in practice. The sufficient sequentiality constraint featured in the standard may thus be downgraded to a necessary atomicity constraint: the processes have to run as if they were on their own from the start to the end of their execution. This leaves opportunities to parallelize the evaluation phase of a SystemC simulation.

The main cause of non-atomicity of processes in the case of a parallel evaluation stems from interprocess interactions. Specifically, SystemC does not constrain the processes to communicating only through channels, as provided by the jargon (common in RTL modelling), and the inputs of which are modified only during the update phase, providing a form of isolation during the evaluation phase. By contrast, notably in TLM modelling, the update phase is of less importance and the interactions take place primarily during the evaluation phase.

For these purposes, all of the functionalities offered by C++ language are able to be used within a SystemC process. In particular, it is possible to access and modify shared memory areas without any particular prior protection. If multiple processes access one and the same memory area at the same time, they may possibly read or write impossible values in the case of a strict sequential execution. It is this type of interaction that constitutes the main risk of non-atomicity of processes and that the invention specifically deals with. Process atomicity violations are called conflicts in the remainder of the present application.

The invention has a mechanism that guarantees the atomicity of processes that interact only via shared memory. It is moreover possible to reproduce a past simulation from a trace stored in a file.

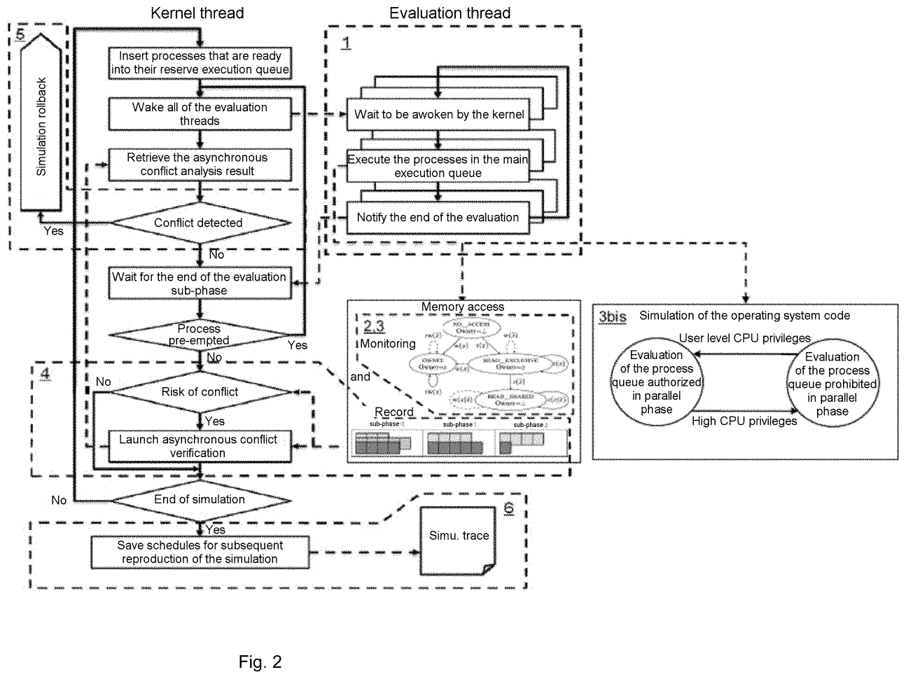

FIG. 2 schematically shows six separate interacting components of the invention, allowing the parallel simulation of SystemC models:

parallel scheduling 1 of processes, for example in process queues, the processes in one and the same queue being assigned to one and the same logic core. Of course, as a variant, the parallel scheduling may also resort to distributing the processes through global sharing, that is to say that each evaluation thread executes a pending process taken from the global queue of processes that have to be evaluated during the present evaluation phase;
dynamically detecting 2 shared addresses of at least one shared memory of a simulated electronic system and avoiding access conflicts, by concurrent processes, to addresses of the shared memory, by pre-empting processes by way of the kernel, using a state machine, respectively associated with each address of the shared memory, determining pre-empting of a process when it introduces a “read after write” or “write after read or write” interprocess dependency, without having beforehand to provide information relating to the use made by the program of the various address ranges;
avoiding access conflicts 3 to addresses of the shared memory by concurrent processes, by pre-empting a process by way of the kernel when said process introduces a “read after write” or “write after read or write” interprocess dependency or when the process simulates a processor whose privilege level 3bis changes from the lower level to a higher level;
verifying access conflicts 4 to shared memory addresses by analysing the interprocess dependencies using a trace of the access operations to the shared memory addresses of each evaluation phase and searching for cycles in an interprocess dependency graph;
rolling back 5, upon detecting at least one conflict, in order to re-establish a past state of the simulation after determining an execution order of the processes of the conflicting evaluation phase during which the conflict is detected, determined from the interprocess dependency graph, in order to avoid the detected conflict in a new simulation that is identical up to the excluded conflicting evaluation phase; and
generating an execution trace 6 for the subsequent identical reproduction of the simulation.

The parallel scheduling makes it possible to execute concurrent processes of a simulation in parallel, for example in execution queues, in which case each execution queue is assigned to a logic core of the host machine. An evaluation phase may then be broken down into a sequence of parallel sub-phases the number of which depends on the existence of processes pre-empted during each evaluation sub-phase. The parallel execution of processes requires precautions in order to preserve their atomicity. To this end, the memory access operations, which represent the most common form of interaction, are instrumented.

When executing the various processes of the simulation, each memory access operation has to be instrumented by a prior call to a specific function. The instrumentation function will determine any interprocess dependencies brought about by the instrumented action. Where applicable, the process at the origin of the action may be pre-empted. It then resumes its execution alongside the other pre-empted processes in a new parallel evaluation sub-phase. These parallel evaluation sub-phases are then strung together until all of the processes have been evaluated in full.

To manage the interactions through access to a shared memory, each address has an associated state machine indicating whether this address is accessible in read mode only to all of the processes or in read and write mode to a single process, depending on the previous access operations to this address. Depending on the state of the address and of the access operation currently being instrumented, the latter is authorized or the process is pre-empted.

This mechanism aims to avoid process evaluation atomicity violations, also called conflicts, but does not guarantee their absence. It is therefore necessary to check for the absence of conflicts at the end of each evaluation phase. When no process has been pre-empted, there is no conflict, as is described in the remainder of the description. If a process is pre-empted, the memory access operations liable to lead to a dependency have moreover been stored in a dedicated structure during the evaluation of the quantum. This structure is used by an independent system thread to construct an interprocess dependency graph and verify that no conflict represented by a cycle in the graph exists. This verification takes place while the simulation continues. The simulation kernel recovers the results in parallel with a subsequent evaluation phase.

In the event of a conflict, a rollback system makes it possible to return to a past state of the simulation before the conflict. When an error occurs, the cause of the error is analysed using the interprocess dependency relationships and the simulation is resumed at the last savepoint before the conflict. The scheduling to be applied in order to avoid reproducing the conflict is transmitted to the simulation before it resumes. The simulation moreover resumes in “simulation reproduction” mode, described in the remainder of the description, which makes it possible to guarantee a simulation result that is identical from one simulation to the next. This prevents the conflict point from being moved due to a lack of determinism of the parallel simulation, and prevents it from occurring again.

The present invention makes it possible to detect sections of simulated code belonging to the simulated operating system (kernel code) and to evaluate them sequentially. This guarantees that no circular dependency is able to be formed due to the kernel code alone. Some dependencies may still form, but a circular dependency will necessarily stem partially from code outside the kernel.

The kernel code has the particular feature of generally being executed under a higher “privilege level”. This allows the processor to perform actions that are impossible in a lower privilege level, such as accessing peripherals. It is in fact generally necessary to resort to the functionalities of the operating system for this precise reason: the intended action requires a higher privilege level that means having to resort to the services of the operating system.

There are generally multiple ordered privilege levels, the lowest of which is called the lower level (for example user level) and the highest of which, the number of which is determined, are called the higher levels.

The implementation is therefore as follows: when an increase in the privilege level of a simulated processor is detected 3bis, the process of the corresponding processor is immediately suspended so as to resume during a sequential sub-phase. The process will be evaluated again in a parallel sub-phase only at the start of the evaluation phase following the return of the privilege level to the lower level.

The privilege level of a processor is generally modelled within a simulator using a simple integer numerical variable the value of which corresponds directly to the privilege level of the processor. It is necessary to supply the simulation kernel with the modifications of this variable in order to suspend the corresponding process where applicable.

It should be noted that the hypothesis according to which the processes interact only via the shared memory of the model is not limiting. Specifically, with the method consisting in sequentially executing processes simulating processors in a high privilege level, the order of the interactions of any kind is constrained in the same way and circular dependencies of any origin are prevented, provided that the dependencies stem from the kernel code.

The simulation reproduction uses a trace that is generated in a past simulation to reproduce the same result. This trace substantially represents a partial order in which the processes have to be executed during each evaluation phase. It is stored in a file or any other persistent storage means between two simulations. Partial order is the name given to an order that is not complete, i.e. an order that does not make it possible to classify all of the elements with respect to one another. In particular, the processes between which no order relationship is defined may be executed in parallel.

The invention does not require prior knowledge of the shared addresses or to be in read mode only to work, thereby allowing greater usage flexibility. Any conflicts are then managed by a simulation rollback solution. It also exhibits a level of parallelism greater than similar solutions.

The invention makes it possible to guard against a significant risk of circular dependency, which leads to the simulation frequently rolling back, which greatly increases the simulation time.

It reliably identifies a major source of circular dependencies and offers an effective countermeasure. The mechanism of suspending/resuming processes is used to sequentially evaluate processes simulating processors in a high privilege level.

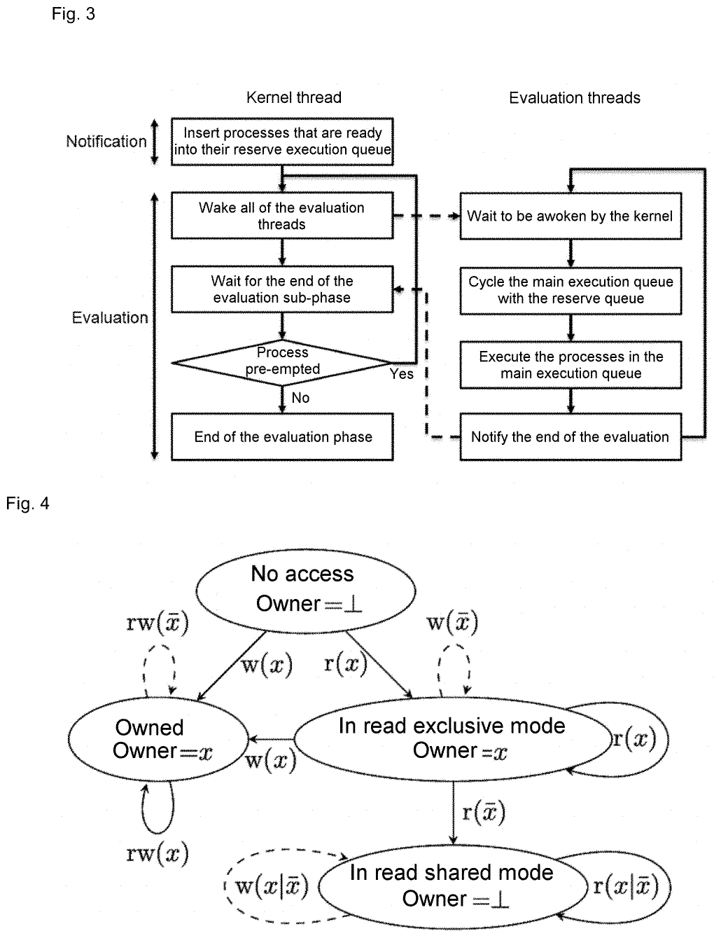

FIG. 3 schematically illustrates the parallel scheduling of processes with the use of process queues. As a variant, instead of using process queues, it is possible to use a distribution of the processes through global sharing, that is to say that each evaluation thread executes a pending process taken from the global queue of the processes that have to be evaluated during the present evaluation phase.

In the remainder of the description, without limitation, the use of process queues is described more particularly.

The parallel execution of a discrete event simulation is based on parallel scheduling of processes. The scheduling proposed in the present invention makes it possible to evaluate concurrent processes of each evaluation phase in parallel. To this end, the processes are assigned to various execution queues. The processes in each execution queue are then executed in turn. The execution queues are however executed in parallel with one another by various system threads, called evaluation threads.

One embodiment offering the best performance consists in allowing the user to statically associate each process of the simulation with an execution queue and to associate each execution queue with a logic core of the simulation platform. However, it is possible to perform this distribution automatically at the start of a simulation or even dynamically using a load balancing algorithm, such as the one known as “work stealing”.

An execution queue may be implemented using three queues, the detailed use of which will be described in the remainder of the description: the main queue containing the processes to be evaluated during the ongoing evaluation sub-phase, the reserve queue containing the processes to be evaluated in the following evaluation sub-phase, and the ended process queue containing the processes the evaluation of which has ended.

The threads are then scheduled in a manner distributed between the simulation kernel and the various execution queues according to FIG. 3, which all have a dedicated system thread and, preferably, a dedicated logic core.

The evaluation phase starts at the end of one of the three possible notification phases (instant, delta or temporal). At this stage, the processes that are ready to be executed are placed in the various reserve execution queues of each evaluation thread. The kernel then awakes all of the evaluation threads, which then initiates the first evaluation sub-phase. Each of these threads cycles its reserve queue with its main queue, and consumes the processes in the latter one by one (the order is not important). A process may end in two ways: either it waits for a call to the function or wait clause or “wait( )”, or it is pre-empted due to a memory access operation introducing a dependency with a process in another evaluation queue.

In the first case, the process is removed from the main execution queue and placed in the list of ended processes. In the second case, it is transferred into the reserve execution queue. Once all of the processes are pre-empted or ended, the first parallel evaluation sub-phase is ended. If no process has been pre-empted, the evaluation phase is ended. If at least one process has been pre-empted, then a new parallel evaluation sub-phase is initiated. All of the threads executing the execution queues are then reawoken and reiterate the same procedure. The parallel evaluation sub-phases are thus repeated until all of the processes are ended (i.e. reach a call to wait( )).

The invention is based on monitoring the interactions through access operations to shared memory that are produced by all of the processes evaluated in parallel. The aim is to guarantee that the interleaving of the memory access operations resulting from the parallel evaluation of the execution queues is equivalent to an atomic evaluation of the processes. In the opposite case, there is a conflict. Only access operations to shared addresses are able to cause conflicts, the other access operations being independent of one another. In order to increase the usage flexibility of the proposed parallel SystemC kernel and reduce the risk of errors relating to declarations of shared memory areas, the invention comprises dynamic detection of shared addresses that does not require any prior information from the user. It is thus possible to pre-empt processes accessing shared memory areas and therefore risking bringing about conflicts.

The technique presented here is based on instrumenting all of the memory access operations. This instrumentation is based on the identifier ID of the process performing an access operation and on the evaluation thread executing it, on the type of access operation (read or write) and on the addresses accessed. This information is processed using the state machine of FIG. 4, instantiated once per memory address accessible on the simulated system. Each address may thus be in one of the following four states:

“no access” (No_access), when the state machine has been reset, without a process defined as owner of the address;
“owned” (Owned) when the address has been accessed by a single process including once in write mode, said process then being defined as owner of the address;
“in read exclusive mode” (Read_exclusive) when the address has been accessed exclusively in read mode by a single process, said process then being defined as owner of the address; and
“in read shared mode” (Read_shared) when the address has been accessed exclusively in read mode by at least two processes, without a process defined as owner of the address.

In this case, the pre-empting of a process by the kernel is determined when:

write access is requested to an address of the shared memory by a process that is not the owner in the state machine of the address, and the current state is other than “no access”; or
read access is requested to an address of the shared memory, the state machine of which is in the “owned” or “read exclusive” state, by a process other than the process owning the address in the state machine of the address.

As a variant, each address may be in one of the following four states:

“no access” (No_access), when the state machine has been reset, without a process queue defined as owner of the address;
“owned” (Owned) when the address has been accessed by a single process queue including once in write mode, said process queue then being defined as owner of the address;
“in read exclusive mode” (Read_exclusive) when the address has been accessed exclusively in read mode by a single process queue, said process queue then being defined as owner of the address; and
“in read shared mode” (Read_shared) when the address has been accessed exclusively in read mode by at least two process queues, without a process queue defined as owner of the address.

In this case, the pre-empting of a process by the kernel is determined when:

write access is requested to an address of the shared memory by a process queue that is not the owner in the state machine of the address, and the current state is other than “no access”; or
read access is requested to an address of the shared memory, the state machine of which is in the “owned” or “read exclusive” state, by a process queue other than the process queue owning the address in the state machine of the address.

In this state machine, the owners are evaluation threads (and not individual SystemC processes), that is to say the system thread responsible for evaluating the processes listed in its evaluation queue. This makes it possible to prevent the processes in one and the same evaluation queue from blocking one another, since it is guaranteed that they are not able to run simultaneously.

The transitions shown in unbroken lines between the states define access operations authorized during the parallel evaluation phase, and those in broken lines define access operations that cause the pre-empting of the process; r and w correspond respectively to read and write; x is the first evaluation thread to access the address since the last reset, and x̅ is any evaluation thread other than x.

The “owned” state Owned indicates that only the owner of the address is able to access it and the “in read shared mode” state Read_shared indicates that only read operations are authorized for all of the evaluation threads. The “in read exclusive mode” state Read_exclusive is important when the first access operation to an address after a reset of the state machine is a read operation by a thread T. If the “in read exclusive mode” state Read_exclusive were not to be present and a read operation by a thread T were to lead immediately to a transition to the “in read shared mode” state Read_shared, T would no longer be able to write to this address without being pre-empted, even if no other process accessed this address in the meantime. This would typically concern all of the addresses in the memory stack of the processes executed by T, and would therefore lead to quasi-systematic pre-empting of all of the processes of T and of all of the processes of the other threads in the same way. With the “in read exclusive mode” state Read_exclusive, it is possible to wait for a read operation from another thread x̅ or else a write operation from x in order to decide on the nature of the address under consideration with greater reliability.

A process is pre-empted as soon as it attempts to perform an access operation that would put the shared address into a state other than “in read only mode” since the last reset of the state machine. This corresponds to a write operation to an address by a process whose evaluation thread is not the owner Owner (unless in the “no access” state No_access) or to a read access operation to an address in the “owned” state Owned and whose owner Owner is another evaluation thread. These pre-empting rules guarantee that, between two resets, it is impossible for an evaluation thread to read (respectively write) an address previously written to (respectively written to or read) by another evaluation thread. This therefore guarantees the absence of dependencies linked to memory access operations between the processes of two separate evaluation queues between two resets.

In order to implement this technique, a register memory access function RegisterMemoryAccess( ) taking the address of an access operation, its size and its type (read or write) as argument is made available to the user. Said user has to call this function before each memory access operation. This function retrieves the identifier of the calling process and its evaluation thread, and the instance of the state machine associated with the accessed address is updated. Depending on the transition performed, the process may either continue and perform the instrumented memory access operation or be pre-empted so as to continue in the following parallel sub-phase.

The state machines are stored in an associative container the keys of which are addresses and the values of the instances of the state machine shown in FIG. 3. This container should support the access operation and the concurrent modification. This has been implemented in two different ways, notably depending on the size of the simulated memory space. When it is possible to have all of the state machines pre-allocated contiguously (for example in an std::vector in C++), this solution is preferred since it offers minimum access times to the state machines. This technique should be preferred for example on systems using a physical memory space of 32 bits or fewer. For larger memory spaces, a multilevel page table-type structure may be used (page is the name given to a contiguous and aligned set of addresses of a given size, such as a few Mb). This structure requires a larger number of indirections (typically three) to access the desired state machine, but is able to support any size of memory space with a memory cost proportional to the number of pages accessed during the simulation and an access time proportional to the size of the memory space in bits.

Once the state machine of the accessed address has been retrieved, the transition to be performed is determined based on the current state and the features of the access operation currently being instrumented. The transition should be computed and applied atomically using for example a “compare and swap” atomic instruction. In order for this to be effective and not require any additional memory space, all of the fields forming the state of an address should be able to be represented atomically on the largest number of manipulatable bits (128 bits on AMD64), the lower the better. In our case, these fields are one byte for the state of the address, one byte for the identifier ID of the evaluation thread owning the address and two bytes for the reset counter, described in the remainder of the description, for a total of 32 bits. If the atomic update of the state fails, this means that another process has updated the same state machine at the same time. The function of updating the state machine is then recalled so as to attempt the update again. This is repeated until the state machine is successfully updated. One performance optimization consists in not performing the atomic “compare and swap” if the transition that is taken loops back to the same state. This is possible since the access operations that cause a transition that loops back to one and the same state are commutative with all of the other access operations of one and the same evaluation sub-phase. This means that the order in which these access operations that loop back to one and the same state are registered with respect to the access operations that are immediately adjacent in time does not influence the final state of the state machine and does not change any pre-empted processes.

The function of updating the state machine of the accessed address finally indicates whether or not the calling process should be pre-empted by returning for example a Boolean.

In order to resume the execution of a process only once the processes on which it depends have ended, it is sufficient, in the following evaluation sub-phase, to verify whether the expected processes have ended. If this is not the case, the process is pre-empted again, otherwise it carries on. The list of ended processes is constructed by the kernel at the end of each evaluation sub-phase in which at least one process has been pre-empted. For these purposes, the kernel to this end aggregates the lists of ended processes from each evaluation thread.

The state machines are used to determine the nature of the various addresses and to authorize or not authorize certain access operations depending on the state of these addresses. However, in one application, some addresses may change use. For example, a buffer memory or buffer may be used to store an image that is then processed by several threads thereafter. When the buffer memory is initialized, it is common for only a single thread to access this memory. The SystemC process simulating this thread is then the owner of the addresses contained in the buffer memory. However, in the phase of processing the image, multiple processes access this image in parallel. If the result of the processing of the image is not placed directly in the buffer memory, this should then be completely in the “in read shared mode” state Read_shared. Now, it is impossible to change from the “owned” state Owned to the “in read shared mode” state read_shared without first resetting the state machine, that is to say a forced return to the “no access” state No_access.

Performance is then greatly impacted by the reset policy that is adopted (when and which state machines are reset), and by the implementation of this reset mechanism. One embodiment of the reset policy is as follows, but others may be implemented: when a process accesses a shared address and it is pre-empted, all of the state machines are reset in the next parallel evaluation sub-phase. This is justified by the following observation: an access operation to a shared address is often symptomatic of the situation described above, that is to say that a set of addresses that are first accessed by a given process are then read only by a set of processes or accessed exclusively by another process (it may be said that the data migrate from one thread to another). The state machines of these addresses then have to be reset in order to attain a more suitable new state. However, it is difficult to anticipate exactly which of the addresses should change state. The option that is selected is therefore that of resetting the entire address space based on the fact that the addresses that did not need to be reset will quickly regain their previous state.

Implementing this reset involves a counter C stored with the state machine of each address. Upon each update of the state machine, the value of a global counter C_{g} external to the state machine is passed as an additional argument. If the value of C_{g} differs from that of C, the state machine should be reset before performing the transition and C is updated to the value C_{g}. Thus, to trigger the reset of all of the state machines, it is sufficient to increment C_{g}. The counter C should be atomically updated with the state of the state machine and any owner of the address.

In the case described above, C uses two bytes. This means that, if C_{g} is incremented exactly 65 536 times between two access operations to a given address, C and C_{g} remain equal and the reset does not take place, thereby potentially, and very unusually, leading to needless pre-emptions, but not compromising the validity of the technique.

This reset technique makes it possible not to have to reset all of the state machines accessed between two evaluation phases for example. This would lead to very significant slowing. In the proposed solution, it is the evaluation threads that perform the reset when needed when they access an address.

With regard to the a posteriori verification of conflicts, as explained above, it is not possible to introduce any dependency between processes belonging to separate execution queues between two resets of the state machines, since any process attempting a memory access operation that would introduce such a dependency is pre-empted before being able to perform its access operation. If no process has been pre-empted at the end of the first parallel evaluation sub-phase, this means that there is no dependency between the execution queues. Now, the processes in one and the same execution queue are evaluated successively, preventing the occurrence of a circular dependency between them within a given evaluation sub-phase. Therefore, there is no circular dependency between all of the processes, and therefore no conflict. No additional verification is therefore necessary if an evaluation phase consists only of a single evaluation sub-phase. In practice, the majority of the evaluation phases require only a single sub-phase, and are therefore immediately guaranteed to be conflict-free. This specific feature of the invention is one of its greatest acceleration factors.

However, if some processes have been pre-empted during the first parallel evaluation sub-phase, multiple parallel evaluation sub-phases take place and dependencies may occur, with the risk of a conflict. It is therefore necessary to verify the absence of conflicts at the end of the complete evaluation phase in these cases. This verification is performed a posteriori, that is to say that the interprocess dependencies are not established during the evaluation phase, but once it has ended, and for example asynchronously. To this end, an access record structure “AccessRecord” containing all of the memory access operations performed during an evaluation phase is used. This structure makes it possible to concurrently store the access operations performed in each parallel evaluation sub-phase.

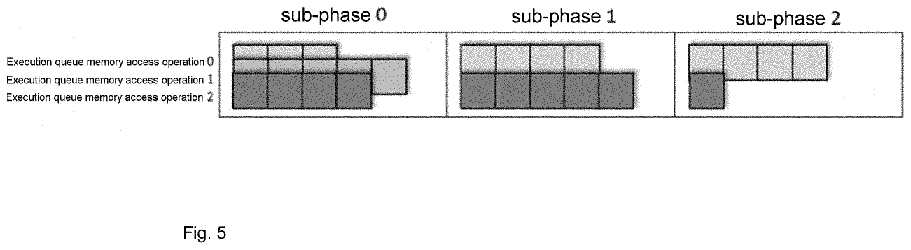

By virtue of the guarantee of the absence of dependency in each parallel evaluation sub-phase, the order, between the execution queues, of the access operations recorded during each sub-phase is not important. These access operations may therefore be recorded in parallel in multiple independent structures. The record structure “AccessRecord” therefore consists, for each sub-phase, of one vector per execution queue, as shown in FIG. 5. Any ordered data structure may be used instead of the vector. At the end of the register memory access “RegisterMemoryAccess( )” function call, if the calling process is not pre-empted, it inserts the features of the instrumented memory access operation into the vector of its execution queue: address, number of bytes accessed, access type and ID of the process.

At the end of each evaluation phase, if multiple sub-phases have taken place, the simulation kernel entrusts the verification of the absence of a conflict to a dedicated system thread. In order not to have to systematically create a new thread without waiting for the verification of a previous evaluation phase to end, a pool of threads is used. If no thread is available, a new thread is added thereto. The verification of the evaluation phase is then performed asynchronously while the simulation continues. Another access record structure “AccessRecord”, itself from a pool, is used for the following evaluation phase.

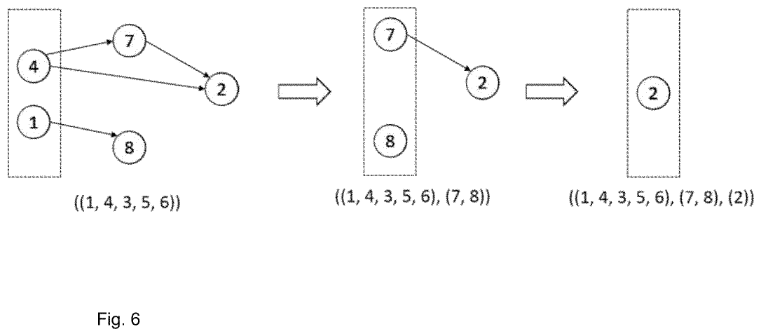

The verification thread then enumerates the access operations contained in the access record structure “AccessRecord” from the first to the last evaluation sub-phase. The vectors of each sub-phase of the access record structure “AccessRecord” should be processed one after the other in any order. A read operation at a given address introduces a dependency with the last writer of this address, and a write operation introduces a dependency with the last writer and all of the readers therefrom. This rule does not apply when a dependency concerns a process with itself. An interprocess dependency graph is thus constructed. Once the graph has been completed, its peaks are all of the processes involved in a dependency, which are themselves represented by oriented arcs. There is then a search for cycles in the graph in order to detect a potential circular dependency between processes that is symptomatic of a conflict. If no cycle, and therefore no conflict, is present, then a list of sets of processes is produced according to their level in the dependency graph: nodes not having any predecessor are grouped with processes that are not featured in the graph; the other nodes are grouped such that no dependency exists in each group and the groups are of a maximum size. An algorithm is illustrated in FIG. 6 with eight processes comprising the following steps:
step 1: group the processes without a predecessor and those not featured in the graph,
step 2: remove the already grouped processes from the graph;
step 3: if processes remain, group the processes without a predecessor, else end.
step 4: resume at step 2.

It is this list of groups of processes that is used in the simulation reproduction described in the remainder of the description.

The result of a conflict verification is retrieved by the simulation kernel in parallel with a subsequent evaluation phase. Once said simulation kernel has awoken the evaluation threads, it tests whether verification results are ready before waiting for the end of the ongoing evaluation sub-phase. If at least one verification result is ready, the kernel retrieves a structure indicating the verified phase, whether a conflict has taken place and, in the absence of a conflict, the list of groups of processes described above. This list may then be used to identically reproduce the ongoing simulation at a later time. One performance optimization consists in reusing the access record structure “AccessRecord”, that has just been verified, in a subsequent evaluation phase. This makes it possible to preserve the buffer memories of the underlying vectors. If the latter were to be reallocated in each evaluation phase, performance would be reduced.

The instrumentation of the memory access operations using the register memory access function “RegisterMemoryAccess( )” aims, firstly, to avoid the occurrence of conflicts and, secondly, to verify a posteriori that the access operations performed in a given evaluation phase actually correspond to a conflict-free execution. In order for this verification to be reliable, it is necessary for the order in which the access operations are recorded in an access record structure “AccessRecord” to effectively correspond to the order of the access operations actually performed. Consideration will be given to the example of two processes P0 and P1 both performing an access operation to an address A. These write operations should be preceded by a call to the register memory access function “RegisterMemoryAccess( )” before being applied to memory. With P0 and P1 running in parallel, the observed order of the calls to the register memory access function “RegisterMemoryAccess( )” may differ from the observed order of the resultant write operations. This order reversal could completely invalidate the validity of the disclosed method: if the recorded order of two write operations is reversed from the real order of the write operations, then the recorded dependency is reversed from the real dependency, and conflicts could pass by unnoticed.

One simple method for guarding against this problem consists in grouping each memory access operation and the call to the register memory access function “registerMemoryAccess( )” preceding it into a section protected by mutual exclusion or “mutex”. This solution is functionally correct but drastically slows down the simulation. On the contrary, one crucial property of the invention dispenses completely with synchronization. Specifically, as explained above, any memory access operation that leads to a dependency gives rise to the process responsible being pre-empted before it is able to perform this access operation. Therefore, no dependency is able to occur between two processes belonging to separate execution queues. In particular, it is impossible for two access operations that lead to a dependency to take place in the same evaluation sub-phase, and therefore for a dependency relationship to be reversed.

With regard to the retrieval of conflicts, when the conflict verification indicates that a conflict has occurred, the simulation no longer complies with the SystemC standard starting from the evaluation phase exhibiting a conflict. The invention is based on a system of rolling back in order to re-establish the simulation in a previous valid state.

Any rollback method could be used. The embodiment presented here is based on a technique of rolling back on the system process level. The CRIU (acronym for “Checkpoint/Restore In Userspace”) tool available on Linux may be used. This makes it possible to write, to files, the state of a complete process at a given time. This includes in particular an image of the memory space of the process along with the state of the processor registers useful at the time of backup. It is then possible, from these files, to relaunch the saved process from the savepoint. CRIU also makes it possible to perform incremental process backups. This consists in writing to the drive only memory pages that have changed since the last backup, and exhibits a significant speed increase. CRIU may be monitored via an RPC interface based on the Protobuf library.

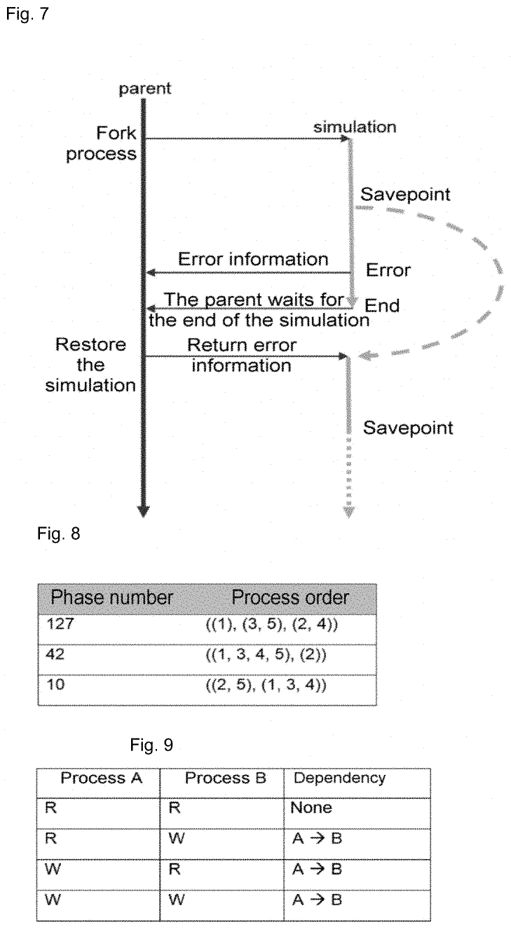

The general principle of the rollback system is shown schematically in FIG. 7. When the simulation is launched, the process of the simulation is immediately duplicated using the fork(2) system call. It is imperative that this duplication takes place before the creation of additional threads, since these are not duplicated by the fork(2) call. The child process that is obtained will be called the simulation, and it is this that performs the actual simulation. During the simulation, there are successive savepoints until eventually encountering an error that corresponds to a conflict. In this case, the simulation process transmits, to the parent process, the information relating to this conflict, notably the number of the evaluation phase in which the conflict occurred and information useful for reproducing the simulation up to the conflict point, as described in the remainder of the description. The execution order to be applied in order to avoid the conflict may then be transmitted. This is obtained by removing one arc per loop in the dependency graph of the phase that caused the conflict and by applying the algorithm for generating the list of groups of processes. The parent process then waits for the simulation process to end before relaunching it using CRIU. Once the simulation process has been re-established in a state prior to the error, the parent process returns, to the simulation process, the information relating to the conflict that caused the rollback. The simulation may then resume and the conflict may be avoided. Once the conflicting evaluation phase has passed, a new backup is performed.

The effectiveness of the invention is based on an appropriate backup policy. The spacing between the backups should specifically be chosen so as to limit the number thereof as far as possible while still avoiding any rollback from returning to an excessively old backup. The first backup policy consists in performing saving only at the very start of the simulation and then waiting for the first conflict, if it occurs. This is very well suited to simulations that cause no or few conflicts. Another policy consists in saving the simulation at regular intervals, for example every 1000 evaluation phases. It is also possible to vary this saving interval by increasing it in the absence of a conflict and by reducing it following a conflict, for example. When a savepoint is reached, the simulation kernel starts by waiting for all of the conflict verifications of the previous evaluation phases to end. If no conflict has occurred, a new backup is performed.

With regard to the reproduction of a simulation, the proposed SystemC simulation kernel is able to operate in simulation reproduction mode. This mode of operation uses a trace generated by the simulation to be reproduced. This trace then makes it possible to monitor the execution of the processes so as to guarantee a simulation result identical to the simulation that produced the trace, thus complying with the requirements of the SystemC standard. The trace used by the invention is formed from the list of numbers of the evaluation phases during which interprocess dependencies occurred, with which are associated the orders in which these processes should be executed in each of these evaluation phases in order to reproduce the simulation. One example is given in the table of FIG. 8, in which, for each listed phase, each process group (inner brackets) is able to be executed in parallel, but the groups should be executed in separate sequential sub-phases. This trace is stored in a file (for example through serialization) between two simulations or any other persistent storage means following the end of the simulation process.

The simulation reproduction uses two containers: one, called Tw (for “Trace write”), used to store the trace of the ongoing simulation, and the other, called Tr (for “Trace read”), containing the trace of a previous simulation passed as a parameter of the simulation if the simulation reproduction is activated. A new element is inserted into Tw following each end of conflict verification. Tw is serialized into a file at the end of each simulation.

If the simulation reproduction is activated, Tr is initialized at the start of the simulation using the trace of a simulation passed as an argument of the program. At the start of each evaluation phase, it is then verified whether its number features among the elements of Tr. If this is the case, the list associated with this phase number in Tr is used to schedule the evaluation phase. To this end, the list of processes to be executed in the next parallel evaluation sub-phase is passed to the evaluation threads. When they are awoken, said evaluation threads verify, before starting the evaluation of each process, that said process is featured in the list. If it is not, the process is immediately placed in the reserve execution queue to be evaluated later.

Tr may be implemented using an associative container with the evaluation phase numbers in the guise of a key, but it is more effective to use a vector-type sequential container in which the pairs (phase number; process order) are stored in decreasing order of evaluation phase numbers (each row of the table in FIG. 8 is a pair of the vector). To verify whether the ongoing evaluation phase is present in Tr, it is then sufficient to compare its number with the last element of Tr and, if they are equal, to remove the latter from Tr at the end of the evaluation phase.

If the simulation reproduction mode is not activated, conflicts may occur followed by a rollback of the simulation. The simulation reproduction mode between the rollback point and the point where the conflict occurred is then activated. This prevents a different conflict from occurring following the rollback due to the non-determinism of the simulation. Tw is then transmitted via the rollback system in order to initialize Tr. In addition to being sorted, the elements corresponding to evaluation phases prior to the return point should be removed from Tr. The simulation reproduction may be deactivated once the conflict point has passed.

One performance optimization consists in deactivating the systems for detecting shared addresses and for verifying conflicts when the simulation reproduction is activated. Specifically, the latter guarantees that the new instance of the simulation provides a result identical to the reproduced simulation. Now, the trace obtained at the end thereof makes it possible to prevent any conflicts that could occur. In the case of a rollback, however, it is important to deactivate the simulation reproduction mode after the conflict point if this optimization is used.

It is assumed that each of the processors of a SystemC model is simulated by a SystemC process. In each evaluation phase, each of the processes simulates a certain number of instructions until the time “quantum” is consumed. The time “quantum” describes the simulated time for which a process is authorized to continue without handing over to the following process. Using a time quantum allows a process to simulate a larger number of actions at a time, reducing the number of context changes and thus speeding up the simulation. Reference is then made to temporal decoupling. In a conventional discrete event simulation using temporal decoupling, the processes are therefore evaluated one after another, and each process simulates a few tens of to a few thousand instructions at a time before handing over to the following process. If on the other hand the processes are evaluated in parallel, as in the present invention, the SystemC standard requires their evaluation to be equivalent to a sequential evaluation. This is conditional on the interactions occurring when they are evaluated and the order of these interactions.

It is assumed that the various processes of a SystemC simulation interact only through access operations to the shared memory of the simulated model. For example, if, during one and the same evaluation phase, two processes access only memory addresses that the other process does not access, there is no interaction between these processes, which are then independent. They may therefore be evaluated in parallel without the risk of an atomicity violation.

By contrast, if two processes access one and the same address during an evaluation phase and at least one of these access operations is a write operation, one of these two processes becomes dependent on the other. The concept of dependency should be understood here in the sense of a constraint on the equivalent sequential evaluation order of the processes. The issue is specifically that of determining, in the parallel evaluation of the processes, whether there is a sequential evaluation order that generates the same interprocess interactions and in the same order. This is a necessary condition sufficient for complying with the “coroutine semantics” imposed by the SystemC standard. It is then said, at the end of a parallel evaluation, that a process A is dependent on a process B if and only if an equivalent sequential evaluation should evaluate B before A.

FIG. 9 illustrates memory access operations that may introduce a dependency in the sense described above. In the table of FIG. 9, two processes A and B are assumed to access one and the same memory address. The first is A and the second is B. R denotes a read operation and W denotes a write operation. A→B describes the fact that B is dependent on A, and therefore that an equivalent sequential evaluation should evaluate A before B in order to preserve the order of the memory access operations to the address under consideration.

It will now be assumed that A and B access two addresses together, but that the access order is not the same for the two addresses. The dependencies A→B and B→A are then formed. There is then no longer an equivalent sequential evaluation, since A and B have to succeed one another. Reference is made here to a circular dependency A→B→A, synonymous with a process atomicity violation and therefore with a simulation error requiring a rollback. A circular dependency may involve an arbitrary number of processes, such as A→B→C→D→A.

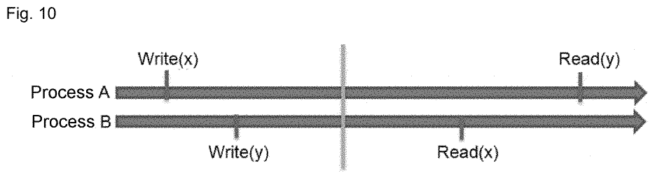

For each access operation to the simulated memory attempted by a process, the present invention determines whether this memory access operation is able to take place immediately or whether the process should be suspended. It is then determined when the process may resume its evaluation. Independently of the scenarios that lead to the suspension of a process and independently of the time at which this process resumes its evaluation, there are some situations that generate an atomicity violation that are virtually impossible to predict. One such example is illustrated in FIG. 10.

In FIG. 10, it is assumed that x and y are two memory addresses that have never been accessed by any of the processes in the past. These are therefore completely ordinary addresses and there is nothing, without extremely in-depth knowledge of the simulated software, to suggest they may be liable to cause a circular dependency. They are the same as any addresses accessed for the first time via a write operation in order to be initialized; an extremely ordinary scenario in computing. At the time represented by the vertical separation, there is no reason not to allow the processes A and B to continue in parallel.

However, the simulated software, during this same evaluation phase, will cause crossing read operations at these same addresses after the vertical separation. The dependencies A→B and then B→A will then be formed, creating a circular dependency and therefore requiring a rollback that is relatively costly in terms of simulation speed. The problem stems from the fact that, up to the time represented by the vertical separation, there was nothing to suggest what would follow. At the same time, regardless of the evaluation order of A and B after the vertical separation, a circular dependency forms and the error is therefore inevitable (except with knowledge of the application for predicting that these addresses will be shared).

This type of scenario generally occurs during what is known as “lockless” code simulation. This is a programming technique that uses what are called atomic processor instructions. These instructions allow multiple processors to simultaneously manipulate the same memory address without leading to incoherence on the final value stored at this address. For example, it is possible to increment the value stored at a given address or to test this value and to replace it if its value is equal to a certain other value, all performed atomically, that is to say without another processor being able to intervene on the address during operation. Using this type of instruction bestows particular properties on a piece of software, properties which are often desirable in the context of an operating system: support for a large number of execution queues sharing numerous resources (memory, file system, etc.) while still preserving an excellent performance level in the majority of circumstances.

Lockless programming techniques are by contrast extremely complex and difficult to use without bugs, limiting their use to a few specific pieces of software for which performance cannot be sacrificed for the benefit of the simplicity of the code. The present invention focuses on preventing circular dependencies during the simulation of lockless code present in the kernel of an operating system. In particular, the invention does not help with managing the lockless code present in the programs executed under an operating system, but only with the management of the code belonging to the operating system itself.

### BIBLIOGRAPHY

SCHM18 T. Schmidt, Z. Cheng, and R. Dömer, “Port call path sensitive conflict analysis for instance-aware parallel SystemC simulation,” in DATE 2018
SCHU10 C. Schumacher, R. Leupers, D. Petras, and A. Hoffmann, “parSC : Synchronous parallel SystemC simulation on multi-core host architectures,” in CODES+ISSS 2010
MELL10 A. Mello, I. Maia, A. Greiner, F. Pecheux, I. M. and A. Greiner, and F. Pecheux, “Parallel Simulation of SystemC TLM 2.0 Compliant MPSoC on SMP Workstations,” in DATE 2010
WEIN16 J. H. Weinstock, R. Leupers, G. Ascheid, D. Petras, and A. Hoffmann, “SystemC-Link: Parallel SystemC Simulation using Time-Decoupled Segments,” in DATE 2016
SCHU13 C. Schumacher et al., “legaSCi: Legacy SystemC Model Integration into Parallel Systemc Simulators,” in IPDPSW 2013.
MOY13 M. Moy, “Parallel programming with SystemC for loosely timed models: A non-intrusive approach,” in DATE 2013
VENT16 N. Ventroux and T. Sassolas, “A new parallel SystemC kernel leveraging many core architectures,” in DATE 2016
LE14 H. M. Le and R. Drechsler, “Towards verifying determinism of SystemC designs,” in DATE 2014
JUNG19 M. Jung, F. Schnicke, M. Damm, T. Kuhn, and N. Wehn, “Speculative Temporal Decoupling Using fork( )” in DATE 2019

1. An electronic system-level reproducible parallel discrete event simulation method implemented by way of a multicore computing system, said simulation method comprising a succession of evaluation phases, implemented by a simulation kernel executed by said computing system, comprising the following steps:
parallel scheduling of processes;
dynamically detecting shared addresses of at least one shared memory of a simulated electronic system by concurrent processes, at addresses of the shared memory, using a state machine, respectively associated with each address of the shared memory;
avoiding access conflicts to addresses of the shared memory by concurrent processes, by pre-empting a process by way of the kernel when said process introduces a “read after write” or “write after read or write” interprocess dependency or when the process simulates a processor whose privilege level (3bis) changes from the lower level to a higher level;
verifying access conflicts to shared memory addresses by analysing the interprocess dependencies using a trace of the access operations to the shared memory addresses of each evaluation phase and searching for cycles in an interprocess dependency graph;
rolling back, upon detecting at least one conflict, in order to re-establish a past state of the simulation after determining a conflict-free execution order of the processes of the conflicting evaluation phase during which the conflict is detected, in a new simulation that is identical up to the excluded conflicting evaluation phase; and
generating an execution trace for the subsequent identical reproduction of the simulation.

2. The method according to claim 1, wherein the parallel scheduling of processes uses queues of at least one process, the processes in one and the same queue being executed sequentially by a system thread associated with a logic core.

3. The method according to claim 1, wherein the execution of a queue of at least one process, the execution of which was suspended following the pre-empting of one of its processes by the kernel, is resumed in a subsequent parallel sub-phase if the pre-empting is due to said process introducing a “read after write” or “write after read or write” interprocess dependency, or is resumed in a subsequent sequential sub-phase if the pre-empting is due to the logic core executing the process changing from a lower privilege level to a higher privilege level.

4. The method according to claim 1, wherein the rollback uses backups of states of the simulation during the simulation that are performed by the simulation kernel.

5. The method according to claim 1, wherein the state machine of an address of the shared memory comprises the following four states:
“no access” (No_access), when the state machine has been reset, without a queue of at least one process defined as owner of the address;
“owned” (Owned) when the address has been accessed by a single queue of at least one process including once in write mode, said queue then being defined as owner of the address;
“in read exclusive mode” (Read_exclusive) when the address has been accessed exclusively in read mode by a single queue of at least one process, said queue then being defined as owner of the address; and
“in read shared mode” (Read_shared) when the address has been accessed exclusively in read mode by at least two queues of at least one process, without a queue defined as owner of the address.

6. The method according to claim 5, wherein the pre-empting of a process by the kernel is determined when:
write access is requested to an address of the shared memory by a queue of at least one process that is not the owner in the state machine of the address, and the current state is other than “no access”; or
read access is requested to an address of the shared memory, the state machine of which is in the “owned” or “read exclusive” state, by a queue of at least one process other than the queue owning the address in the state machine of the address.

7. The method according to claim 5, wherein all of the state machines of the addresses of the shared memory are regularly reset to the “no access” state.

8. The method according to claim 5, wherein all of the state machines of the addresses of the shared memory are reset to the “no access” state during the evaluation phase following the pre-empting of a process.

9. The method according to claim 1, wherein access conflicts to shared memory addresses during each evaluation phase are verified asynchronously, during the execution of subsequent evaluation phases.

10. The method according to claim 1, wherein the execution trace for the subsequent identical reproduction of the simulation comprises a list of numbers representative of evaluation phases associated with a partial evaluation order of the processes defined by the interprocess dependency relationships of each evaluation phase.

11. The method according to claim 1, wherein a rollback, upon detection of at least one conflict, re-establishes a past state of the simulation, and then reproduces the simulation identically up to the evaluation phase that produced the conflict and then executes its processes sequentially.

12. The method according to claim 1, wherein a rollback, upon detection of at least one conflict, re-establishes a past state of the simulation, and then reproduces the simulation identically up to the evaluation phase that produced the conflict and then executes its processes in a partial order deduced from the dependency graph of the evaluation phase that produced the conflict after having removed one arc per cycle therefrom.

13. The method according to claim 1, wherein a state of the simulation is saved at regular intervals of evaluation phases.

14. The method according to claim 1, wherein a state of the simulation is saved at intervals of evaluation phases that increase in the absence of detection of a conflict and decrease following detection of a conflict.

15. A computer program product comprising program code instructions recorded on a computer-readable medium for implementing the steps of the method according to claim 1 when said program is executed on a computer.
